(19) United States
(12) Patent Application Publication
(10) Pub. No.: US 2026/0126480 A1
(43) Pub. Date: May 7, 2026

(54) ELECTRONIC CONTROL UNIT AND FAULT INFORMATION TRANSMISSION CIRCUIT

(71) Applicant: Robert Bosch GmbH, Stuttgart (DE)

(72) Inventors: Xiaofei Qiu, Suzhou (CN); Ruediger Karner, Bietigheim-Bissingen (DE)

(21) Appl. No.: 19/240,667

(22) Filed: Jun. 17, 2025

(30) Foreign Application Priority Data
Jun. 21, 2024 (CN) 2024 1080 9108.9

(51) Int. Cl. G01R 31/00; B60R 16/023

(52) U.S. Cl. CPC G01R 31/006; B60R 16/023

(57) ABSTRACT

The present application relates to an Electronic Control Unit (ECU), which includes a first chip and a second chip. The first chip comprises a first fault information transmission circuit, and the second chip comprises a second fault information transmission circuit. The first fault information transmission circuit comprises: a single fault pin, coupled to the fault pin of the second chip, configured to transmit and receive fault information; a current detection circuit, configured to detect whether current is present in the first fault information transmission circuit; a voltage regulation unit, configured to receive a voltage input from within the first chip and to output a fault voltage only when a fault is present in the voltage input; a back-to-back protection circuit, coupled between the single fault pin and the voltage regulation unit; and a fault monitoring circuit, configured to monitor the fault voltage output by the voltage regulation unit or the fault information received by the single fault pin from the second chip. The present application further relates to a fault information transmission circuit.

### TECHNICAL FIELD

The present application relates to the field of fault information transmission, and more particularly, to an electronic control unit (ECU, Electronic Control Unit) and a fault information transmission circuit.

### BACKGROUND

In an electronic control unit system (e.g., an airbag ECU), an application specific integrated circuit chip ASIC provides functions such as ignition loop drivers, PSI interfaces, and power supply. To support a greater number of such functions, multiple ASICs are sometimes employed within the ECU system.

In the event of a fault, these faults may occur in any one of the ASICs and may also be transmitted to other ASICs. Therefore, it is necessary to share fault information among the different ASICs.

### SUMMARY OF THE INVENTION

The inventors of this application recognize that there is a limit to the number of pins available on ASICs, making it not appropriate to use multiple pins to share fault information among different chips. Moreover, in the prior art, there is no technical solution that allows the identification of the fault source (i.e., which specific chip has encountered a fault) and/or the fault type using only a single fault pin across multiple chips.

According to one aspect of the present application, an Electronic Control Unit (ECU) is provided. The ECU includes a first chip and a second chip. The first chip comprises a first fault information transmission circuit, and the second chip comprises a second fault information transmission circuit. The first fault information transmission circuit includes: a single fault pin, coupled to the fault pin of the second chip, configured to transmit and receive fault information; a current detection circuit, configured to detect whether current is present in the first fault information transmission circuit; a voltage regulation unit, configured to receive an internal voltage input of the first chip and to output a fault voltage only when a fault occurs in the voltage input; a back-to-back protection circuit, coupled between the single fault pin and the voltage regulation unit; the back-to-back protection circuit is configured to transmit the fault voltage output by the voltage regulation unit to the single fault pin when the current detection circuit detects the presence of current in the first fault information transmission circuit; and the back-to-back protection circuit is further configured to prevent the fault information received by the single fault pin from the second chip from being transmitted to the current detection circuit and the voltage regulation unit; and a fault monitoring circuit, configured to monitor the fault voltage output by the voltage regulation unit or the fault information received by the single fault pin from the second chip.

In other words, the single fault pin in the first fault information transmission circuit is coupled to the fault pin in the second fault information transmission circuit, thereby enabling fault information to be transmitted among multiple chips. Moreover, in addition to the single fault pin, the first fault information transmission circuit further includes a current detection circuit, a voltage regulation unit, a back-to-back protection circuit, and a fault monitoring circuit. Through the coordinated interaction among these circuits/units, the determination of fault-related information is facilitated, such as identifying the fault source (i.e., whether the fault originates from the first chip or another chip) and the fault type, among others.

As a supplement or alternative to the above solution, in the aforementioned ECU, the first chip and the second chip are application-specific integrated circuit chips.

As a supplement or alternative to the above solution, in the aforementioned ECU, the first fault information transmission circuit and the second fault information transmission circuit have the same circuit structure.

As a supplement or alternative to the above solution, in the aforementioned ECU, the fault monitoring circuit comprises: a first monitoring resistor; a second monitoring resistor; and a voltage monitoring node located between the first monitoring resistor and the second monitoring resistor; the voltage at the voltage monitoring node is capable of indicating the type of fault that has occurred; one end of the first monitoring resistor is coupled to the single fault pin and the back-to-back protection circuit; the other end of the first monitoring resistor is coupled to one end of the second monitoring resistor; and the other end of the second monitoring resistor is grounded.

As a supplement or alternative to the above solution, in the aforementioned ECU, when a fault occurs in the voltage input, the current detection circuit is capable of detecting current within the first fault information transmission circuit.

As a supplement or alternative to the above solution, in the aforementioned ECU, the voltage regulation unit includes a switching element. The switching element is configured to be coupled with the current detection circuit and to conduct only when a fault occurs in the voltage input, thereby enabling the current detection circuit to detect current within the first fault information transmission circuit.

As a supplement or alternative to the above solution, in the aforementioned ECU, the switching element is a MOS transistor.

As a supplement or alternative to the above solution, in the aforementioned ECU, the voltage regulation unit further comprises: an operational amplifier and a grounding resistor, wherein the positive input of the operational amplifier receives the voltage input, and the negative input is coupled to one end of the grounding resistor, with the other end of the grounding resistor connected to ground. The output of the operational amplifier is coupled to the gate of the MOS transistor. The drain of the MOS transistor is coupled to the current detection circuit, the source of the MOS transistor is coupled to one end of the grounding resistor, and the source of the MOS transistor is further coupled to the single fault pin via the back-to-back protection circuit.

As a supplement or alternative to the above solution, the ECU may further include a third chip, wherein the third chip comprises a third fault information transmission circuit. The third fault information transmission circuit has the same circuit structure as the first and second fault information transmission circuits. In other words, the single fault pin in the first fault information transmission circuit is coupled to the fault pins of both the second and third fault information transmission circuits, thereby enabling fault information to be transmitted among the multiple chips.

According to another aspect of the present application, a fault information transmission circuit is provided. The fault information transmission circuit is disposed within a first chip and comprises: a single fault pin, coupled to a fault pin of a second chip (i.e., a chip different from the first chip), configured to transmit and receive fault information; a current detection circuit, configured to detect whether current is present in the fault information transmission circuit; a voltage regulation unit, configured to receive an internal voltage input of the first chip and to output a fault voltage only when a fault occurs in the voltage input; a back-to-back protection circuit, coupled between the single fault pin and the voltage regulation unit, configured to transmit the fault voltage output by the voltage regulation unit to the single fault pin when the current detection circuit detects the presence of current in the fault information transmission circuit; the back-to-back protection circuit is further configured to prevent the fault information received by the single fault pin from the second chip from being transmitted to the current detection circuit and the voltage regulation unit; and a fault monitoring circuit, configured to monitor the fault voltage output by the voltage regulation unit or the fault information received by the single fault pin from the second chip.

### BRIEF DESCRIPTION OF THE DRAWINGS

The foregoing and other objectives and advantages of the present application will become more fully apparent from the following detailed description taken in conjunction with the accompanying drawings, in which identical or similar elements are denoted by the same reference numerals.

FIG. 1 illustrates a schematic structural diagram of an ECU according to one embodiment of the present application.

FIG. 2 illustrates a circuit schematic diagram of the first fault information transmission circuit in the ECU according to one embodiment of the present application; and

FIG. 3 illustrates a structural schematic diagram of the fault information transmission circuit according to one embodiment of the present application.

### DETAILED DESCRIPTION OF THE EMBODIMENTS

In the following, the fault information transmission scheme according to various exemplary embodiments of the present application will be described in detail with reference to the accompanying drawings.

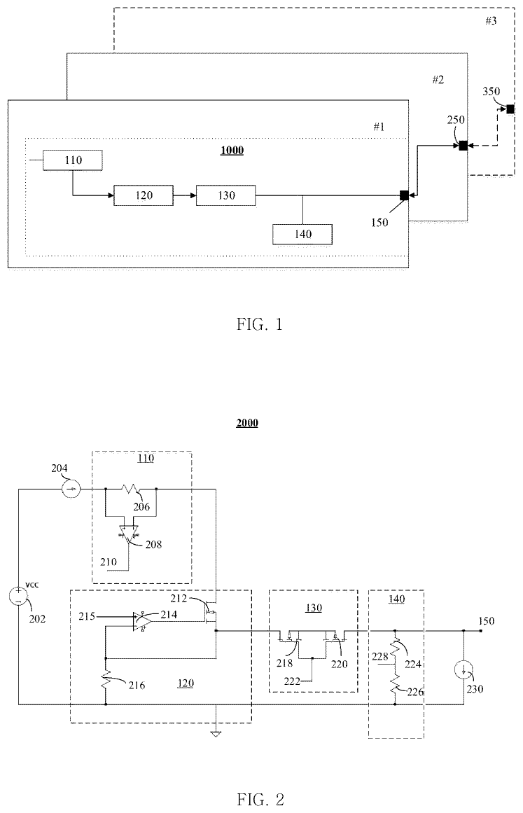

FIG. 1 illustrates a schematic structural diagram of an ECU according to one embodiment of the present application. As shown in FIG. 1, the ECU includes multiple chips (e.g., a first chip #1, a second chip #2, etc.), wherein the first chip #1 includes a first fault information transmission circuit 1000 and the second chip #2 includes a second fault information transmission circuit (not shown in FIG. 1).

In FIG. 1, the first fault information transmission circuit 1000 comprises: a single fault pin 150, the single fault pin 150 is coupled to a fault pin 250 of the second chip #2 for transmitting and receiving fault information.

With continued reference to FIG. 1, in addition to a single fault pin 150, the first fault information transmission circuit 1000 further comprises: a current detection circuit 110, a voltage regulation unit 120, a back-to-back protection circuit 130, and a fault monitoring circuit 140. Wherein, the current detection circuit 110 is configured to detect whether current is present in the first fault information transmission circuit 1000. The voltage regulation unit 120 is configured to receive the internal voltage input of the first chip #1 and to output a fault voltage only when a fault exists in the voltage input. The back-to-back protection circuit 130 is coupled between the single fault pin 150 and the voltage regulation unit 120. The back-to-back protection circuit 130 is configured to transmit the fault voltage output by the voltage regulation unit 120 to the single fault pin 150 when the current detection circuit 110 detects the presence of current in the first fault information transmission circuit 1000. Additionally, the back-to-back protection circuit 130 is further configured to prevent the fault information received by the single fault pin 150 from the second chip #2 from being transmitted to the current detection circuit 110 and the voltage regulation unit 120. The fault monitoring circuit 140 is configured to monitor either the fault voltage output by the voltage regulation unit 120 or the fault information received by the single fault pin 150 from the second chip #2.

It should be noted that, within the context of the present application, the terms “fault pin” or “single fault pin” refer to a pin on the chip used for transmitting or receiving fault-related information, and do not indicate that the pin itself is faulty.

As shown in FIG. 1, in one embodiment, the ECU may include other chips in addition to the first chip and the second chip, such as the third chip #3. It should be noted that the number of chips can be increased as needed and is not limited to 3. Wherein, the third chip #3 includes a third fault information transmission circuit (not shown in the FIG. 1). In one or more embodiments, the third fault information transmission circuit has the same circuit structure as the first fault information transmission circuit 1000 and the second fault information transmission circuit. That is, the single fault pin 150 in the first fault information transmission circuit 1000 is coupled to the fault pin 250 in the second fault information transmission circuit and the fault pin 350 in the third fault information transmission circuit, thereby enabling fault information to be transmitted among the multiple chips.

For a single chip, since only a single fault pin is required to share fault-related information among different chips, pin overhead on the chip can be reduced, making this approach especially suitable for chips with pin number limitations (e.g. ASICs).

In one embodiment, the first chip, the second chip, and the third chip are application-specific integrated circuit chips. The so-called “application-specific integrated circuit chip,” also known as ASIC (Application Specific Integrated Circuit), is a custom integrated circuit designed and manufactured for the needs of a specific user or a particular electronic system, with typically higher performance and lower power consumption than a general purpose integrated circuit. In addition, ASICs can integrate a large number of logic gates, memory, analog circuits, and more onto a single chip, achieving a high degree of integration. For example, in an airbag ECU, the first ASIC may be used to provide an ignition loop driver, while the second ASIC may be used to provide the PSI interface, power supply, and other functions.

Moreover, it should be noted that, although not shown in FIG. 1, in one embodiment, the first fault information transmission circuit 1000 may further include: a power supply (such as a voltage source, current source, etc.) configured to supply power to the first fault information transmission circuit 1000; a voltage controller configured to control the voltage regulation unit 120 and a back-to-back drive unit for driving the back-to-back protection circuit 130.

Referring to FIG. 2, it illustrates a circuit schematic diagram of a first fault information transmission circuit 2000 according to one embodiment of the present application. Similar to the first fault information transmission circuit 1000 in FIG. 1, the first fault information transmission circuit 2000 in FIG. 2 also includes: a single fault pin 150, a current detection circuit 110, a voltage regulation unit 120, a back-to-back protection circuit 130, and a fault detection circuit 140. In addition, the first fault information transmission circuit 2000 further comprises: a voltage source VCC 202 (e.g., 6.7 V), a current source 204 (e.g., 1 mA), and a current sink 230 (e.g., 100 μA). Wherein, one end of the voltage source VCC 202 is coupled with one end of the current source 204, the other end of the voltage source VCC 202 is grounded, the other end of the current source 204 is coupled with the current detection circuit 110. One end of the current sink 230 is coupled with the single fault pin 150, and the other end of the current sink 230 is grounded.

In the embodiment of FIG. 2, the current detection circuit 110 includes a detection resistor 206 and a current detection unit 208, wherein the current detection unit 208 determines whether current is present in the circuit based on the voltage across the detection resistor 206. In one embodiment, the current detection unit 208 is an operational amplifier, whose non-inverting input is coupled to one end of the detection resistor 206, and inverting input is coupled to the other end of the detection resistor 206. The output terminal 210 thereof represents the detection result (e.g., when current is present in the first fault information transmission circuit 2000, the output terminal 210 is at a high logic level; otherwise, the output terminal 210 is at a low logic level).

In one embodiment, as shown in FIG. 2, the voltage regulation unit 120 includes a switching element 212. The switching element 212 is configured to couple with the current detection circuit 110 and to conduct only when a fault occurs in the voltage input 215, thereby allowing the current detection circuit 110 to detect current within the first fault information transmission circuit 2000. In one embodiment, the switching element 212 is a MOS transistor (e.g., an NMOS).

With continued reference to FIG. 2, the voltage regulation unit 120 further comprises: an operational amplifier 214 (acting as an “voltage control unit”) and a grounding resistor 216 (e.g., 100 k ohm), wherein non-inverting input of the operational amplifier 214 receives the internal voltage input 215 of the chip, while the inverting input of the operational amplifier 214 is coupled to one end of the grounding resistor 216, the other end of 216 is connected to ground. The output of the operational amplifier 214 is coupled to the gate of the MOS transistor 212. The drain of the MOS transistor 212 is coupled to the current detection circuit 110, the source of the MOS transistor 212 is coupled to one end of the grounding resistor 216. And the source of the MOS transistor 212 is further coupled to the single fault pin 150 via the back-to-back protection circuit 130.

In one embodiment, the back-to-back protection circuit 130 includes a first back-to-back transistor 218 and a second back-to-back transistor 220, wherein the drain of the first back-to-back transistor 218 is coupled to the voltage regulation unit 120, the source of the first back-to-back transistor 218 is coupled to the source of the second back-to-back transistor 220. The drain of the second back-to-back transistor 220 is coupled to the fault monitoring circuit 140, the fault pin 150. Additionally, the gate of the first back-to-back transistor 218 and the gate of the second back-to-back transistor 220 are both controlled by the back-to-back control signal 222. For example, the back-to-back control signal 222 may be generated by the chip (e.g., an ASIC chip), and is configured such that when the current detection circuit 110 detects the presence of current in the first fault information transmission circuit 2000, the fault voltage output by the voltage regulation unit 120 is transmitted to the single fault pin 150 (i.e., both the first and second back-to-back transistors 218 and 220 are turned on). In all other cases, the first and second back-to-back transistors 218 and 220 are turned off to prevent fault information received at the fault pin 150 from other chips from being (inadvertently) transmitted back to the current detection circuit 110 and the voltage regulation unit 120.

In one embodiment, the fault monitoring circuit 140 includes: a first monitoring resistor 224 (e.g., 100 k Ohms); a second monitoring resistor 226 (e.g., 10 k Ohms); and a voltage monitoring node 228 positioned between the first monitoring resistor 224 and the second monitoring resistor 226, wherein the voltage at the voltage monitoring node 228 is able to indicate the type of failure that has occurred. One end of the first monitoring resistor 224 is coupled to the single fault pin 150 and the back-to-back protection circuit 130. The other end of the first monitoring resistor 224 is coupled to one end of the second monitoring resistor 226, and the other end of the second monitoring resistor 226 is connected to ground.

In one embodiment, the relationship between the voltage at the voltage monitoring node 228 and the fault type is shown in the following table:

| | |
|---|---|
| Voltage | Fault Type |

| | | |
|---|---|---|
| 0 | V | Normal state |
| 0.5 | V | Overvoltage protection of the first power rail (power |
| | | [symbol] |
| 1 | V | Undervoltage of the first power rail |
| 1.5 | V | Overvoltage protection of the second power rail |
| 2 | V | Overvoltage of the second power rail |
| 2.5 | V | Undervoltage of the second power rail |

| | |
|---|---|
| . . . | . . . |

[symbol]

indicates data missing or illegible when filed

It should be noted that the relationship between the voltage at the voltage monitoring node 228 and the fault types shown in the above table is for illustrative purposes only and can be adjusted or modified as needed based on actual requirements.

In this embodiment, the first fault information transmission circuit 2000 is capable of determining both the fault source (i.e., whether the fault originates from the first chip or another chip) and the fault type using only a single fault pin 150. For example, when the voltage at the voltage monitoring node 228 is 0 V, it indicates that both the chip where the first fault information transmission circuit 2000 resides (e.g., the first chip) and the other chips are in a normal state. When the voltage at the voltage monitoring node 228 is not 0 V, such as 2 V, the source of the fault is further determined by the output 210 of the current detection circuit 110. If the current detection circuit 110 detects a current in the first fault information transmission circuit 2000, it indicates that the fault originates from the local chip (i.e., the first chip). If no current is detected by the current detection circuit 110 in the first fault information transmission circuit 2000, it indicates that the fault originates from another chip (e.g., the second chip). Moreover, as previously described, the fault type (such as undervoltage, overvoltage protection, or overvoltage) can be further determined based on the voltage at the voltage monitoring node 228.

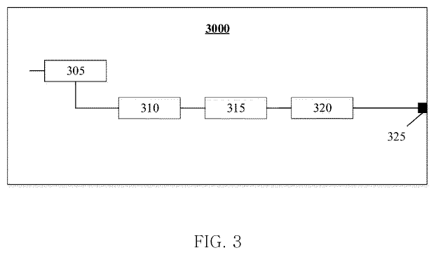

FIG. 3 illustrates a schematic structural diagram of a fault information transmission circuit 3000 according to one embodiment of the present application. The fault information transmission circuit 3000 is disposed within a first chip (not shown in FIG. 3). As shown in FIG. 3, the fault information transmission circuit 3000 comprises: a single fault pin 325, which is coupled to the fault pin of a second chip (i.e., a chip different from the first chip, not shown in FIG. 3), and is used for transmitting and receiving fault information; a current detection circuit 305, configured to detect whether current is present within the fault information transmission circuit 3000; a voltage regulation unit 310, configured to receive a voltage input from within the first chip and to output a fault voltage only when a fault exists in the voltage input; a back-to-back protection circuit 315, coupled between the single fault pin 325 and the voltage regulation unit 310. The back-to-back protection circuit 315 is configured to transmit the fault voltage output by the voltage regulation unit 310 to the single fault pin 325 when the current detection circuit 305 detects current in the fault information transmission circuit 30000. The back-to-back protection circuit 315 is further configured to prevent the received fault information from being transmitted to the current detection circuit 305 and the voltage regulation unit 310 when the single fault pin 325 receives fault information from the second chip; and a fault monitoring circuit 320, configured to monitor the fault voltage output by the voltage regulation unit 310 or the fault information received by the single fault pin 325 from the second chip.

The current detection circuit 305, voltage regulation unit 310, back-to-back protection circuit 315, and fault monitoring circuit 320 in FIG. 3 may be implemented using the same circuits as their corresponding components in FIG. 2, and will therefore not be described further herein.

The above examples primarily illustrate the fault information transmission scheme of the embodiments of the present application. Although only certain embodiments of the present application have been described, those of ordinary skill in the art will understand that the present application may be implemented in many other forms without departing from its spirit and scope. Therefore, the examples and embodiments disclosed herein are to be regarded as illustrative rather than limiting.

Various modifications and substitutions may be made without departing from the spirit and scope of the present application as defined by the appended claims.

1. An electronic control unit (ECU) comprising a first chip and a second chip, wherein the first chip includes a first fault information transmission circuit, and the second chip includes a second fault information transmission circuit, and wherein the first fault information transmission circuit comprises:
a single fault pin, coupled to a fault pin of the second chip, configured to transmit and receive fault information;
a current detection circuit, configured to detect whether a current is present in the first fault information transmission circuit;
a voltage regulation unit, configured to receive a voltage input from within the first chip and to output a fault voltage only when a fault is present in the voltage input;
a back-to-back protection circuit, coupled between the single fault pin and the voltage regulation unit, wherein the back-to-back protection circuit is configured to transmit the fault voltage output by the voltage regulation unit to the single fault pin when the current detection circuit detects the presence of current in the first fault information transmission circuit; and further configured to prevent the received fault information from being transmitted to the current detection circuit and the voltage regulation unit when the single fault pin receives fault information from the second chip; and
a fault monitoring circuit, configured to monitor the fault voltage output by the voltage regulation unit or the fault information received by the single fault pin from the second chip.

2. The ECU according to claim 1, wherein the first chip and the second chip are application-specific integrated circuit chips.

3. The ECU according to claim 1, wherein the first fault information transmission circuit and the second fault information transmission circuit have the same circuit structure.

4. The ECU according to claim 1, wherein the fault monitoring circuit comprises:
a first monitoring resistor;
a second monitoring resistor; and
a voltage monitoring node located between the first monitoring resistor and the second monitoring resistor,
wherein the voltage at the voltage monitoring node is designed to indicate the type of fault that has occurred;
wherein one end of the first monitoring resistor is coupled to the single fault pin and the back-to-back protection circuit, and the other end of the first monitoring resistor is coupled to one end of the second monitoring resistor, and the other end of the second monitoring resistor is grounded.

5. The ECU according to claim 1, wherein the current detection circuit is configured to detect current in the first fault information transmission circuit when a fault is present in the voltage input.

6. The ECU according to claim 5, wherein the voltage regulation unit includes a switching element, and wherein the switching element is configured to be coupled with the current detection circuit and to conduct only when a fault exists in the voltage input, thereby enabling the current detection circuit to detect current in the first fault information transmission circuit.

7. The ECU according to claim 6, wherein the switching element is a MOS transistor.

8. The ECU according to claim 7, wherein the voltage regulation unit further comprises: an operational amplifier and a grounding resistor, wherein the non-inverting input of the operational amplifier receives the voltage input, the inverting input of the operational amplifier is coupled to one end of the grounding resistor, and the other end of the grounding resistor is grounded; the output of the operational amplifier is coupled to the gate of the MOS transistor, the drain of the MOS transistor is coupled to the current detection circuit, the source of the MOS transistor is coupled to the one end of the grounding resistor, and the source of the MOS transistor is coupled to the single fault pin via the back-to-back protection circuit.

9. The ECU according to claim 1, wherein the ECU further comprises a third chip, the third chip including a third fault information transmission circuit, and the third fault information transmission circuit has the same circuit structure as the first and second fault information transmission circuits.

10. A fault information transmission circuit, wherein the fault information transmission circuit is disposed within a first chip and comprises:
a single fault pin, coupled to a fault pin of a second chip, configured to transmit and receive fault information;
a current detection circuit, configured to detect whether current is present in the fault information transmission circuit;
a voltage regulation unit, configured to receive a voltage input from within the first chip and to output a fault voltage only when a fault is present in the voltage input;
a back-to-back protection circuit, coupled between the single fault pin and the voltage regulation unit, wherein the back-to-back protection circuit is configured to transmit the fault voltage output by the voltage regulation unit to the single fault pin when the current detection circuit detects the presence of current in the fault information transmission circuit; and further configured to prevent the received fault information from being transmitted to the current detection circuit and the voltage regulation unit when the single fault pin receives fault information from the second chip; and
a fault monitoring circuit, configured to monitor the fault voltage output by the voltage regulation unit or the fault information received by the single fault pin from the second chip.
